(19) United States
(12) Patent Application Publication
(10) Pub. No.: US 2005/0042523 A1
(43) Pub. Date: Feb. 24, 2005

(54) Endpoint detection of plasma-assisted etch process

(76) Inventors: Banqiu Wu, Austin, TX (US); Y. David Chan, Austin, TX (US)

Correspondence Address: AMSTER, ROTHSTEIN & EBENSTEIN;90 PARK AVENUE, NEW YORK, NY, 10016, US

(21) Appl. No.: 10/644,358

(22) Filed: Aug. 20, 2003

(51) Int. Cl. G03F 9/00; G03C 5/00; G01R 31/00; B44C 1/22; C03C 25/68; C03C 15/00; C23F 1/00; G01L 21/30

(52) U.S. Cl. 430/5; 216/58; 216/59; 430/322; 430/323

(57) ABSTRACT

A method for detecting endpoint of plasma-assisted etch process by monitoring a parameter of the etch process, such as an automatic matching network parameter, and detecting a predetermined change in the parameter signaling the endpoint. This novel endpoint detection method has advantages of, inter alia, simplicity and reliability, is very cost-effective and requires minimum change to the etch process system hardware. It is particularly useful in the manufacture of photomasks and products manufactured using photomasks.

### FIELD OF THE INVENTION

The present invention relates to control of plasma-assisted etch processes. In particular, the present invention relates to endpoint detection for plasma-assisted etch processes. Even more particularly, the present invention relates to control of plasma-assisted etch processes in the manufacture of photomasks and products manufactured with photomasks and the like.

### BACKGROUND OF THE INVENTION

### PHOTOMASK MANUFACTURING PROCESSES

There are a wide variety of photomasks known in the art, as well as diverse uses to which they can put, as described in, e.g., U.S. Pat. Nos. 6,472,107 and 6,567,588. Among the many types of photomasks used in the semiconductor industry, binary and phaseshift photomasks are quite common. A typical binary photomask is comprised of a substantially transparent substrate 2 and opaque layer 4, in which a pattern is formed, as shown in a cross-sectional illustration of an unprocessed binary photomask in FIG. 1A. Further, the opaque layer 4 may also have an anti-reflective (“AR”) coating 6. The pattern of the opaque material in the opaque layer 4 and AR material in the AR coating 6 on the substantially transparent substrate 2 may be a scaled negative of the image desired to be formed on the semiconductor wafer. For a typical chrome-on-glass (“CoG”) or binary photomask, the substantially transparent substrate 2 is comprised of quartz. The opaque material 4 is comprised of chromium (“Cr”) and the AR material is comprised of chromium oxide (“CrO”)

A binary photomask used in the production of semiconductor devices is formed from a “blank” photomask. As shown in FIG. 1A, a prior art blank photomask 1 is commonly comprised of at least four layers. The first layer 2 is a substantially transparent substrate, such as quartz, commonly referred to as the substrate. The next layer above the substantially transparent layer 2 is an opaque layer 4, which is comprised of Cr in the case of a typical CoG photomasks. Thereafter, although not always necessary, there may be an AR layer 6 integral to the opaque layer, which in the case of CoG photomasks is comprised of CrO. A layer of photosensitive resist material 8 resides as the top layer. In the case of CoG photomasks, the photosensitive resist material 8 is typically a hydrocarbon polymer, the various compositions and thicknesses of which are well known in the art. Other layers may also be present for alternative reasons, as is described, for example, in U.S. Pat. No. 6,472,107. Similarly, other materials may be used as is well known in the art.

The desired pattern of opaque material to be created on the photomask may be defined by an electronic data file loaded into an exposure system which typically scans an electron beam (E-beam) or laser beam in a raster fashion across the blank photomask. One such example of a raster scan exposure system is described in U.S. Pat. No. 3,900,737. As the E-beam or laser beam is scanned across the blank photomask, the exposure system directs the E-beam or laser beam at addressable locations on the photomask as defined by the electronic data file. In the case of a positive photoresist, the areas that are exposed to the E-beam or laser beam become soluble, while the unexposed portions remain insoluble. In the case of a negative photoresist, the unexposed areas become soluble, while the exposed portions remain insoluble. As shown in FIG. 1B, after the exposure system has scanned the desired image onto the photosensitive resist material, the soluble photosensitive resist is removed by means well known in the art, and the insoluble photosensitive resist material 8a remains adhered to the next layer (e.g., the AR layer 6).

After undergoing the foregoing photolithographic process, as illustrated in FIG. 1C, the exposed layer of AR material 6 and the underlying layer of opaque material 4 are no longer covered by the photosensitive resist material 8a and are removed by a well known etch process. Only the portions of the layer of AR material 6a and the layer of opaque material 4a residing beneath the remaining photosensitive resist material 8a remain affixed to the substantially transparent substrate 2. This initial or base etching may be accomplished by either a wet etching or dry etch process, both of which are well known in the art. In general, wet-etch processes use a liquid acid solution to erode away the exposed AR material 6 and Cr opaque material 4. Such processes are not pertinent to the present invention. A dry etch process, which is known in the art, may include plasma-assisted etch such as reactive ion etching (RIE), and utilizes electrified gases, such as a mixture of chlorine (Cl₂) and oxygen (O₂) in the case of a CoG photomasks, to remove the exposed CrO AR material 6 and/or Cr opaque material 4. For other types of materials, such as MoSi type phaseshift photomasks discussed below, a mixture of fluorine (F₂) and oxygen (O₂) may be used. The appropriate gases and concentrations of such gases are generally well known in the art, such as taught in U.S. Pat. Nos. 6,406,818 and 6,562,549.

A plasma-assisted etch process may be conducted in an etch chamber in which etching gases, such as chlorine and oxygen in the case of CoG photomasks, or other gases in the case of other materials to be etched, are injected. A radio frequency (RF) electromagnetic energy may be provided by an RF generator coupled to a power supply and may be applied between two parallel plate electrodes (i.e., anode and cathode). One example of etching equipment providing such plasma-assisted etch process is the Centura P5000 etcher manufactured by Applied Materials. This coupling of the RF energy from the RF generator (the “source”) to the plate electrodes of the plasma system (the “load”) generates a reactive gas plasma from the injected chlorine and oxygen gases.

FIG. 2 illustrates a typical plasma-assisted etch system 28. Etching is performed in etch chamber 22 on a photomask or other material to be etched, which is placed on an electrostatic chuck or bottom electrode 24 (labeled “ESC Cathode”). bias RF power 26 is connected to the bottom electrode 24 to generate DC bias and ionic bombardment on the photomask or wafer. It is common to have another power source 20 coupled to the plasma-assisted etch system to generate inductively coupled plasma (ICP) to increase the ionic concentration and thereby enhance the etch process. Other types of plasma generating devices are also well known in the art, such as Plasma Therm VLR 770 by Unaxis, which also uses ICP and bias RF plasma.

During the plasma-assisted etch process for a typical photomask, positive ions of the reactive gas plasma are accelerated toward the photomask which is oriented such that the surface area of the substrate is perpendicular to the electrical field. The ion bombardment enhances the etch rate of the exposed areas of opaque material and/or AR material in the vertical direction but not in the horizontal direction (i.e., the etching is anisotropic or directional).

In the case of CoG photomasks, the reaction between the reactive gas plasma and the Cr opaque material and/or CrO AR material is a two step process. First, a reaction between the chlorine gas and exposed CrO AR material and/or Cr opaque material forms chromium radical species. The oxygen then chemically reacts with the chromium radical species to create a volatile resulting complex substance (e.g., ClOCr) which can “boil off,” thereby removing the exposed CrO AR material and the exposed Cr opaque material.

After the etch process is completed the photosensitive resist material is stripped away by a process well known in the art. The dimensions of the remaining opaque material and AR material on the processed photomask are then measured to determine whether or not critical dimensions are within specified tolerances. If not, additional processes may be used to repair the photomask as are known in the art, such as described in U.S. Pat. Nos. 6,406,818 and 6,562,549.

Another type of photomask used for transferring images to a semiconductor wafer is commonly referred to as a phaseshift photomask. Phaseshift photomasks are generally preferred over binary photomasks when the design to be transferred to the semiconductor wafer includes smaller, tightly packed feature sizes which are below the resolution requirements of optical equipment being used. Phaseshift photomasks are engineered to be 180 degrees out of phase with light transmitted through etched areas on the photomask so that the light transmitted through the openings in the photomask is equal in amplitude.

One type of phaseshift photomask is commonly referred to as an embedded attenuated phaseshift mask (EAPSM). Other types of phaseshift masks are also known, and the teachings of the present invention may be equally applied thereto. As shown in FIG. 3A, a typical blank EAPSM 31 may be comprised of four layers. The first layer is a typically a substantially transparent material 33 (such as quartz, for example) and is commonly referred to as a substrate. The next layer is typically an embedded phaseshifting material (“PSM layer”) 35, such as molybdenum silicide (MoSi), tantalum silicon nitride (TaSiN), titanium silicon nitride (TiSiN), zirconium silicon oxide (ZrSiO), or other known phase materials. The next layer is typically an opaque material 37, such as chromium, which may optionally include an anti-reflective coating such as chromium oxynitride (CrON). The top layer is a photosensitive resist material 39, as is well known in the art.

The method for processing a conventional EAPSM is now described. As with binary photomasks, the desired pattern of the opaque material to be created on the EAPSM is typically scanned by an electron beam (E-beam) or laser beam in a raster or vector fashion across a blank EAPSM 31. As the E-beam or laser beam is scanned across the blank EAPSM 31, the exposure system directs the E-beam or laser beam at addressable locations on the EAPSM. In the case of a positive photoresist material, the areas that are exposed to the E-beam or laser beam become soluble, while the unexposed portions remain insoluble. In the case of a negative photoresist, the unexposed areas become soluble, while the exposed portions remain insoluble.

As is done with binary photomasks and as shown in FIG. 3B, after the exposure system has scanned the desired image onto the photosensitive resist material 39, the soluble photosensitive resist material is removed by means well known in the art, and the insoluble photosensitive resist material 39a remains adhered to the opaque material 37. Thus, the pattern to be formed on the EAPSM is formed by the remaining photosensitive resist material 39a.

The pattern is then transferred from the remaining photosensitive resist material 39a to the opaque layer 37 and PSM layer 35 via well known etching techniques, such as plasma-assisted etch described above, by etching away the portions of the opaque layer and PSM layer not covered by the remaining photoresist. After etching is completed, the remaining photoresist material is stripped or removed as shown in FIG. 3C. Other processing steps, such as partial or complete etching of the opaque layer 37a, may be further performed to complete the fabrication of the phaseshift photomask.

### SEMICONDUCTOR PRODUCTION METHODS

Photomasks are used in the semiconductor industry to transfer micro-scale images defining a semiconductor circuit onto a silicon or gallium arsenide substrate or wafer and the like. To create an image on a semiconductor wafer, the photomask is interposed between the semiconductor wafer, which includes a layer of photosensitive material, and an energy source commonly referred to as a Stepper. The energy generated by the Stepper passes through the transparent portions of the substantially transparent substrate not covered by the opaque material (and, if utilized, the anti-reflective and/or phaseshift material) and causes a reaction in the photosensitive material on the semiconductor wafer. Energy from the Stepper is prevented from passing through the opaque portions of the photomask. As with the manufacture of photomasks, when the photosensitive material is exposed to light it will react. Thereafter, the soluble photosensitive material is removed using processes well known in the prior art. The semiconductor wafer is then etched in a manner similar to that described above. After further processing, a semiconductor product is formed.

### AUTOMATIC MATCHING NETWORK

The plasma-assisted etching is optimized by efficient coupling of the RF power from the source to the load (i.e., by achieving the maximum RF power transfer from the RF generator to the electrodes and plasma), which can be achieved by “matching” the output impedance of the source to the input impedance of the load. More specifically, the maximum RF power transfer from the source to the load occurs when the output impedance of the source is the complex conjugate of the input impedance of the load. In general, the load impedance of the plate electrodes in the plasma system does not equal to the complex conjugate of the characteristic impedance of the RF generator. Furthermore, while the impedance of the RF generator remains substantially constant, the value of the load impedance of the plate electrodes in the plasma system varies during the etch process as the inner condition of the vacuum chamber, such as composition of the gases, changes.

Therefore, a matching network is placed in series between the source and load to minimize the loss of the RF power through power reflection or dissipation due to the mismatch between the source and load impedances. As the load impedance varies during the etch process, the components of the matching network comprising variable capacitors and/or variable inductors are adjusted or “tuned” to maintain the conjugate matches between the source and load impedances. When properly tuned, the matching network allows most of the RF power output to be coupled to the plasma, thereby achieving optimal etching condition.

Typically, the tuning of the matching network is done automatically (hence, an automatic matching network or AMN). FIG. 4 shows a schematic diagram of the plasma-assisted etch system employing an AMN. The system comprises control computer 48, RF generator 40, AMN 42 and processing module 44. RF power is generated by the RF generator 40 and is coupled to the plasma in the processing module 44, where the plasma-assisted etch process is performed, via the AMN 42. The computer 48 controls the plasma-assisted etch process by controlling the RF generator 40. The impedance of the RF generator 40 is predetermined and remains substantially constant during the etch process. On the other hand, the impedance of the processing module 44 is dependent on composition of the gases in the etching chamber and properties of the photomask or wafer being etched, and therefore varies as the etch process progresses. During the etch process, the impedances of the RF generator 40 and processing module 44 are continuously monitored and automatically matched by the AMN 42 to ensure the optimal plasma etching condition. This kind of AMN system may be applied to control both bias RF plasma and ICP. However, different parameters may be adjusted to match impedance of different types of plasma. For example, frequency may be adjusted for ICP impedance matching, while capacitance may be adjusted for bias RF plasma impedance matching. In addition, some form of AMN system may be applicable to control bias DC plasma.

### ENDPOINT DETECTION

During the plasma-assisted etch process, it is desirable to detect when the photomask or semiconductor wafer has been etched to a desired level (i.e., the “endpoint” when the portion to be etched has been completely removed) so that the etch process can be stopped before etching away the underlying layers. Various kinds of endpoint detection methods are used to monitor and control the progress of the plasma-assisted etch process, and play a crucial role in quality control of the product that undergoes the etch process. For the production of state-of-art photomasks such as phaseshift masks, which have the strict requirement on phase angle and transmission properties, proper endpoint detection of the plasma-assisted etch process is especially critical. Many photomask properties such as critical dimensions (CD), isolated/dense feature CD bias, pattern radial distribution, and etch CD movement also strongly depend on proper endpoint detection of the etch process.

The two commonly used endpoint detection methods for photomask etch processes are optical interferometry techniques and optical emission spectroscopy techniques. The optical interferometric endpoint detection method is based on reflection of a laser beam from the area being etched, and monitors a change in reflectivity of the etched area to detect the etch endpoint. The accuracy of this method depends on the etch rate at the point of detection and etch rate uniformity.

For the process of etching a MoSi layer on a phaseshift photomask, the difference of reflectivity before and after etch endpoint is typically too small to be accurately detected. Due to this limitation, the optical interferometric method often fails to achieve the precise endpoint detection required by the MoSi etch process. In addition, the optical interferometric method requires a separate endpoint detection device to measure the reflectivity of the reflected beams, thereby increasing the cost and complexity of the plasma etch system. The need for placing the laser beam in advance at a precise position further adds another complexity to the plasma etch process.

Another deficiency of the optical interferometric endpoint detection method is its inability to detect when the endpoint is reached over the whole photomask being etched. Etch rate is generally higher at the edge of the photomask than at the center (i.e., the radial distribution of the etch rate is not uniform). However, the interferometric method typically uses the edge area of the photomask as the point of endpoint detection, and therefore detects the endpoint before the center area of the photomask reaches the endpoint, thereby often prematurely reporting endpoint. Hence, even after the endpoint detection, an overetch has to be performed to compensate for the non-uniformity in the etch rate and endpoints. This is necessary for CD uniformity and for clearing of the etched materials.

Another commonly used endpoint detection method, the optical emission spectroscopy technique, is based on monitoring the change in the optical emission spectrum of the plasma during the plasma-assisted etch process. The optical emission spectrum of the plasma allows the detection of the types and amounts of species within the plasma (i.e., detecting which species of the blank photomask material start appearing in or disappearing from the etch chamber), and is therefore capable of indicating the progress of the etch process. The accuracy of the endpoint detection based on the optical emission spectroscopy depends on detector position, etch load, and selection of wavelength for the optical emission spectrum.

The main disadvantages of this method are the limited sensitivity at low etch load and the complexity and high costs of analysis equipments needed to operate the optical emission spectrum system. Because the optical emission signal is from the gaseous source (i.e., the plasma), the endpoint detection is affected by the gas flow parameters and photomask pattern. The optical emission spectrum is highly influenced by the type of etch materials and position of transducer or optical detector. The selection of emission wavelength for the endpoint detection also has effects on the endpoint detection.

Many patents directed to improving these prior art optical interferometric and optical emission spectroscopic methods have appeared in recent years demonstrating a long-felt need to solve these problems. For example, U.S. Pat. No. 6,228,277 introduced an interferometric in-situ endpoint method based on a single interferometric fringe. U.S. Pat. No. 6,190,927 is directed to an improved method of detecting endpoint based on optical emission spectroscopy when the signal-to-noise ratio in the optical emission signal is extremely low. U.S. Pat. No. 6,207,008 improves the endpoint detection method based on optical emission spectroscopy by optimizing the structure design of the reaction chamber. U.S. Pat. No. 6,258,497 improves the optical emission spectroscopy techniques by adding chemicals on the materials to be etched as a marker. However, the improvements to the optical interferometric and optical emission spectroscopic endpoint detection methods by these patents do not overcome the intrinsic deficiencies of the prior art methods as described above.

A non-optical endpoint detection method for the plasma-assisted etch process was disclosed in U.S. Pat. No. 5,653,894. This patent describes the endpoint detection based on in-situ monitoring of at least two process parameters of the plasma-assisted etch process by a neural network controller. A neural network is a type of artificial intelligence system comprising a complex interconnected web of processing elements for use in, for example, pattern recognition. According to the patent, a statistical analysis is performed to select the signals that exhibit the greatest indication of endpoint. These signals of the etch process parameters (e.g., reflected source power, source match load, RF-bias match load and RF-bias tune) are then used by a complicated algorithm to train the neural network so that the neural network may detect endpoint on its own.

The main disadvantage of this neural-network based endpoint detection method is the increased complexity and costs to the plasma-assisted etch system due to the neural network controller. For example, the neural network controller will not start recognizing endpoint of the plasma-assisted etch process until it attains such capability only after “learning” from several runs of etch processes. Furthermore, the neural network controller can only attain the capability of recognizing endpoint by monitoring and analyzing with complex algorithms sets of at least two etching parameters. Therefore, the neural network controller would require a large computational power to process the monitored data from the plasma etch process. In addition, the need for monitoring at least two plasma process parameters by the neural network system further adds complexity to the etch system.

Furthermore, the patent only describes the application of this endpoint detection method to semiconductor wafers, and does not disclose whether the same method would also be applicable to photomasks. The neural-network based endpoint detection method as disclosed in U.S. Pat. No. 5,653,894 would be applicable to batch processing of semiconductor wafers in which many parts of the wafer, or many wafers, of the identical composition are processed. Through the repeated processes, the neural network can be trained to recognize endpoints and then applied to control the plasma etch system. In the photomask production process, however, each part of the photomask to be etched is unique, and therefore, the photomask etch process would not provide adequate opportunity for a neural network to train itself to recognize endpoint. Therefore, even if this non-optical endpoint detection method can overcome many of the intrinsic limitations of the optical interferometric and optical emission spectroscopic methods, it suffers from its own deficiencies and complexity that may not be desirable for someone looking for a simple, but reliable endpoint detection method of the plasma-assisted etch process. In the photomask production, in particular, an endpoint detection method that is applicable to each unique etch process, and that does not require training from several runs of etch processes to recognize endpoint is desirable.

It is also known in the art that the changes in the plasma impedance during the etch process causes changes in self-bias (or DC bias) voltage generated in asymmetrical reactor geometries. See Daniel L. Flamm & G. Kenneth Herb, Plasma Etching Technology—An Overview, in PLASMA ETCHING: AN INTRODUCTION 76-77 (Dennis M. Manos & Daniel L. Flamm eds., 1989). When etching at constant power, the DC bias voltage reaches a maximum as the etched layer starts to clear and then decreases during the over-etch, thereby providing endpoint information. This is typical in semiconductor wafer processing. For example, a large swing in DC bias is typically observed at endpoint during a resist strip cycle for semiconductor wafer processing. For photomask production, however, the change in DC bias voltage may not be visible, depending upon etch tool design. In fact, some etch tools for photomask production do not even provide readout for DC bias voltage measurement. Therefore, we observe that changes in DC bias cannot be widely used for the purpose of endpoint detection during photomask production.

The present invention seeks to overcome the shortcomings of the prior art endpoint detection methods for plasma-assisted etch processes.

In particular, it is an object of the present invention to provide a simple and reliable endpoint detection method for plasma-assisted etch processes.

It is a further object of the present invention to provide an endpoint detection method for plasma-assisted etch processes that does not require any extra complex equipment.

It is another object of the present invention to provide an endpoint detection method for plasma-assisted etch processes that can be easily implemented with minimum change to the etch system hardware.

It is yet another object of the present invention to provide an endpoint detection method for plasma-assisted etch processes that is cost-effective.

It is another object of the present invention to provide an endpoint detection method for plasma-assisted etch processes that is applicable to photomask production.

It is another object of the present invention to provide an endpoint detection method for plasma-assisted etch processes, wherein the endpoint detection can be achieved by monitoring parameters of the plasma etch system.

It is another object of the present invention to provide an endpoint detection method for plasma-assisted etch processes, wherein the endpoint detection is achieved by monitoring changes in automatic matching network parameters.

It is another object of the present invention to provide an endpoint detection method for plasma-assisted etch processes, wherein the endpoint detection can be achieved by monitoring only one parameter of the plasma etch system.

It is another object of the present invention to provide an endpoint detection method for plasma-assisted etch process, wherein the endpoint detection can be achieved by detecting a predetermined change in a parameter of the plasma etch system.

It is another object of the present invention to provide an endpoint detection method for plasma-assisted etch processes that does not depend on the position of the endpoint detection.

It is another object of the present invention to provide an endpoint detection method for plasma-assisted etch processes that does not depend on the signal size for a change in a parameter of the plasma etch system at endpoint.

Other objects and advantages of the present invention will become apparent from the following description.

### SUMMARY OF THE INVENTION

It has now been found that the above and related objects of the present invention are obtained in the form of several related aspects, including a method for detecting endpoint of a plasma-assisted etch process in the manufacture of a photomask.

The method for detecting endpoint of a plasma-assisted etch process in production of a photomask may comprise the steps of: providing a blank photomask comprising a photosensitive resist layer on the top of the blank photomask; creating soluble and insoluble portions in the photosensitive resist layer; removing soluble portions of the photosensitive resist layer, thereby exposing an underlying layer of the blank photomask; commencing the plasma-assisted etch process on the underlying layer of the blank photomask; defining the endpoint in the form of a predetermined change in at least one of parameters of the plasma-assisted etch process; monitoring the at least one of the parameters; and detecting the predetermined change in the at least one of the parameters; and controlling the plasma-assisted etch process based on the detection of the predetermined change in the at least one of the parameters.

Alternatively, the method for detecting endpoint of a plasma-assisted etch process in production of a photomask may comprise the steps of: providing a blank photomask comprising a photosensitive resist layer on the top of the blank photomask; creating soluble and insoluble portions in the photosensitive resist layer; removing soluble portions of the photosensitive resist layer, thereby exposing an underlying layer of the blank photomask; commencing the plasma-assisted etch process on the underlying layer of the blank photomask; defining the endpoint in the form of a change in one parameter of the plasma-assisted etch process; monitoring the one parameter; and detecting the change in the one parameter; and controlling the plasma-assisted etch process based on the detection of the change in the one parameter.

Yet another alternative method for detecting endpoint of a plasma-assisted etch process in production of a photomask, wherein the plasma-assisted etch process uses an automatic matching network, may comprise the steps of: providing a blank photomask comprising a photosensitive resist layer on the top of the blank photomask; creating soluble and insoluble portions in the photosensitive resist layer; removing soluble portions of the photosensitive resist layer, thereby exposing an underlying layer of the blank photomask; commencing the plasma-assisted etch process on the underlying layer of the blank photomask; defining the endpoint in the form of a predetermined change in at least one of automatic matching network parameters; monitoring the at least one of the automatic matching network parameters; and detecting the predetermined change in the at least one of the automatic matching network parameters; and controlling the plasma-assisted etch process based on the detection of the predetermined change in the at least one of the automatic matching network parameters.

The step of controlling the plasma-assisted etch process may include the step of terminating the plasma-assisted etch process. The step of controlling the plasma-assisted etch process may be performed manually, or automatically. The step of automatically controlling the plasma-assisted etch process may comprise the step of using an algorithm. The monitoring step may be performed automatically and may comprise the step of using an algorithm. Likewise, the detecting step may be performed automatically and may comprise the step of using an algorithm.

The step of monitoring may include the step of modifying a signal display of the monitored parameter(s) so that changes in the monitored parameter(s) can be displayed. This step may involve amplifying, or re-scaling the signal display.

If the plasma-assisted etch process uses an automatic matching network, the monitored parameter(s) may be automatic matching network parameter(s), including an automatic matching network load and tune for either inductively coupled plasma, or bias radio-frequency plasma. For example, the automatic matching network tune may be a capacitance of at least one variable capacitor in the automatic matching network. Another possible monitored parameter for endpoint detection may be a reflected power for inductively coupled plasma. Yet another possible parameter to be monitored for endpoint detection may be a pump rate for a vacuum pump for the etch chamber of the plasma-assisted etch system.

The endpoint detection method of the present invention may be applicable to an etch process using a plasma comprising bias radio-frequency plasma, inductively coupled plasma, or combination thereof, or any other type or multiple types of plasma. The endpoint detection method of the present invention may be applicable to a plasma-assisted etch process comprising reactive ion etch.

The endpoint detection method of the present invention may be applicable to production of various types of photomasks comprising binary and phaseshift photomasks. Additionally, the endpoint detection method of the present invention may be applicable to plasma-assisted etch processes performed on a chromium layer of a binary photomask, a chromium layer of a phaseshift photomask, or a MoSi layer of a phaseshift photomask.

### BRIEF DESCRIPTION OF THE DRAWINGS

The above and related objects, features and advantages of the present invention will be more fully understood by reference to the following, detailed description of the preferred, albeit illustrative, embodiment of the present invention when taken in conjunction with the accompanying figures, wherein:

FIG. 1A is a cross-sectional view of a blank photomask illustrating the composition of the various layers of a typical prior art blank binary photomask.

FIG. 1B is a cross-sectional view of the prior art binary photomask of FIG. 1A after exposure to an energy source and having the soluble photosensitive material removed.

FIG. 1C is a cross-sectional view of the prior art binary photomask of FIGS. 1A-1B after being subjected to an etching process removing the exposed AR material and opaque material.

FIG. 2 illustrates a cross-sectional view of the plasma-assisted etch process system using both bias RF plasma and ICP.

FIG. 3A is a cross-sectional view of a prior art blank EAPSM illustrating the composition of the various layers of such photomask.

FIG. 3B is a cross-sectional view of the prior art EAPSM shown in FIG. 3A after exposure to an energy source and removal of the soluble photosensitive material.

FIG. 3C is a cross-sectional view of the prior art EAPSM of FIGS. 3A-3B after being subjected to an etching process removing the exposed opaque and phase shift layers and after stripping away the remaining photoresist material.

FIG. 4 illustrates schematically a plasma-assisted etch system using automatic matching network.

FIG. 5 is a graph showing ICP reflected power as a function of time during plasma-assisted etching of chromium layer of clear field chromium-resist binary mask and, in particular, the change in the ICP reflected power at endpoint.

FIG. 6 is a graph showing ICP reflected power as a function of time during plasma-assisted etching of chromium layer of dark field chromium-resist binary mask and, in particular, the change in the ICP reflected power at endpoint.

FIG. 7 is a graph showing ICP reflected power as a function of time during plasma-assisted etching of chromium layer of clear field phaseshift mask and, in particular, the change in the ICP reflected power at endpoint.

FIG. 8 is a graph showing ICP reflected power as a function of time during plasma-assisted etching of chromium layer of dark field phaseshift mask and, in particular, the change in the ICP reflected power at endpoint.

FIGS. 9A and 9B are graphs showing AMN load and tune for bias RF plasma, and AMN tune for ICP, respectively, as functions of time during plasma-assisted etching of MoSi layer of clear field phaseshift mask and, in particular, their changes at endpoint.

FIG. 10 is a graph showing AMN tune for ICP as a function of time during plasma-assisted etching of MoSi layer of clear field phaseshift mask and, in particular, its change at endpoint.

### DETAILED DESCRIPTION OF THE INVENTION

The present invention relates to control of plasma-assisted etch processes. In particular, the present invention relates to endpoint detection for plasma-assisted etch processes. The end point detection for plasma-assisted etch processes of the present invention is particularly useful in the manufacture of photomasks and products using photomasks in their manufacture.

The endpoint detection method of the present invention is based on monitoring changes in a parameter of the plasma-assisted etch system. Parameters of the plasma-assisted etch system, such as load impedance as described earlier, are determined by the etch system environment, including plasma setting, gas composition and properties of etched surface, as it evolves during the etch process. As the surface being etched reaches the underlying substrate, the parameters of the etch system environment begin to change. Subsequently, as the surface of the underlying substrate is gradually exposed to the plasma etch environment, a new stable condition is established in the etch parameters. The endpoint detection of the present invention is based on the identification of this transition point in the etch process.

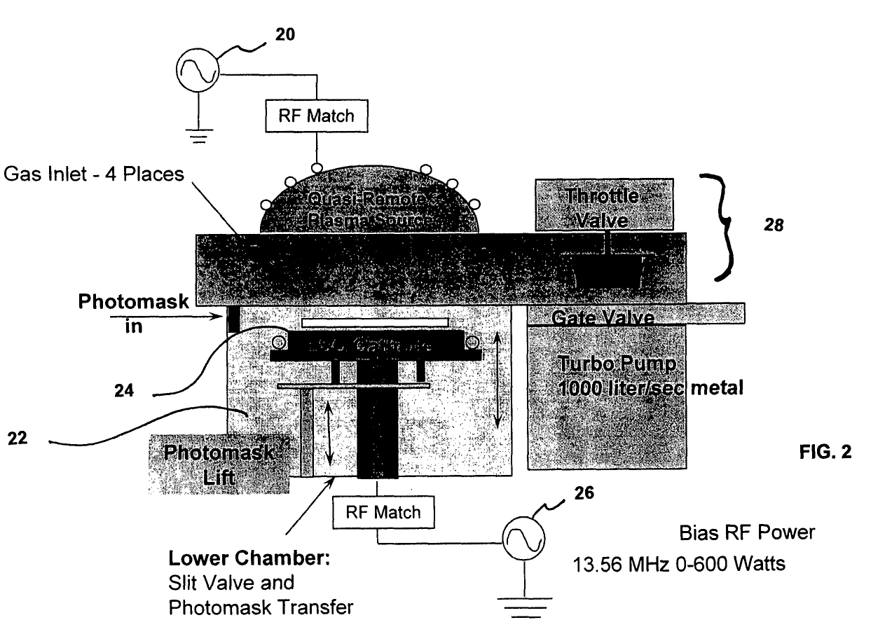

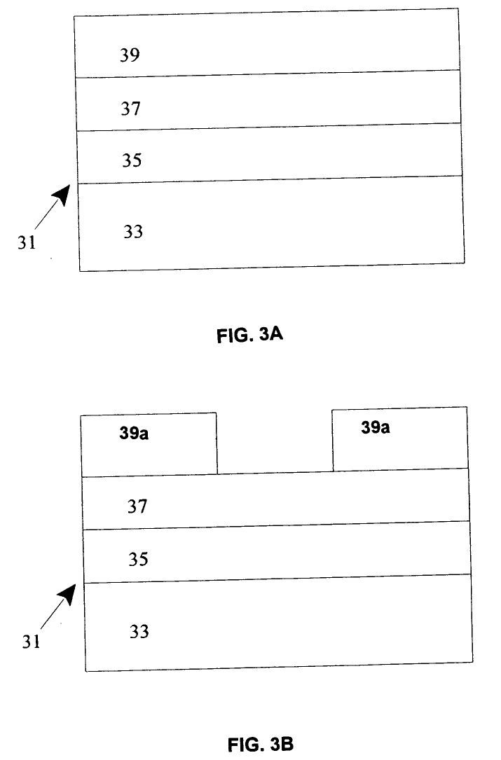

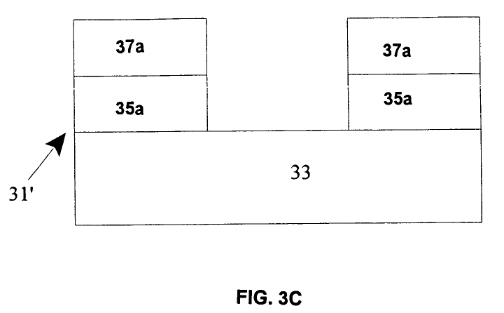

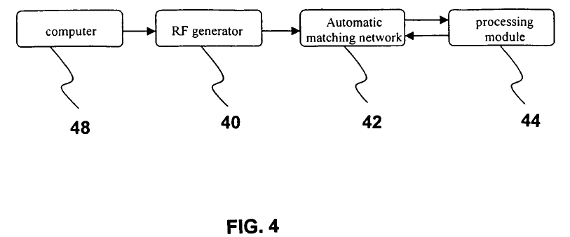

In one embodiment of the present invention based on the plasma-assisted etch system using bias RF plasma 26, ICP 20 and AMN 42 as shown in FIGS. 2 and 4, the endpoint detection may be based on monitoring changes in one of the AMN parameters such as reflected power for ICP, and AMN load and tune for either bias RF plasma, or ICP. The AMN load and tune are measures of absolute or relative magnitudes of capacitance or inductance of variable capacitor(s) or inductor(s) within the AMN as it adjusts these parameters for impedance matching. When the AMN adjusts the variable capacitor(s) for impedance matching, the AMN load refers to a shunt capacitance and the AMN tune refers to a series capacitance. Typically, the magnitudes of these AMN load and tune are measured relative to fixed reference values, which may be specific to etching tool. As described in the Background section, the AMN system 42 measures and monitors changes in, inter alia, AMN tune and load during the etch process, and continually and automatically adjusts these internal parameters to match the source and load impedances for optimal RF power transfer to the load.

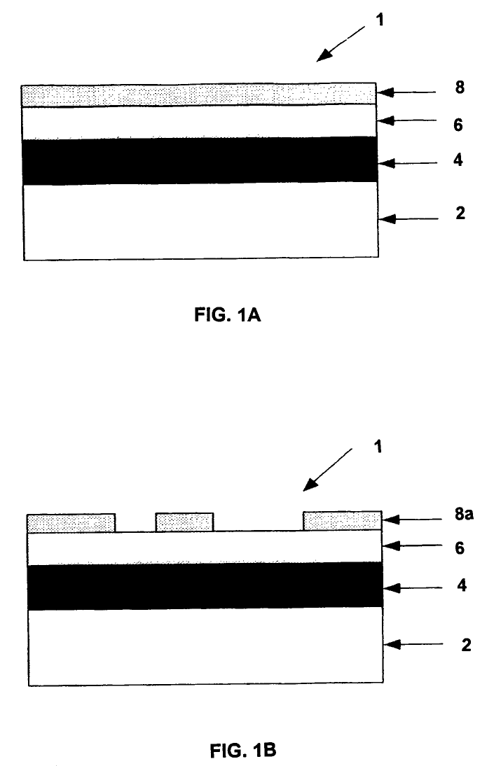

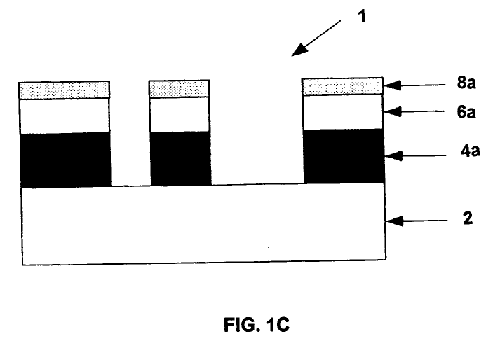

As an illustrative example, let us look at the plasma-assisted etch process of binary photomask as illustrated in FIGS. 1B-1C. Before the endpoint is reached, the exposed surfaces are photoresist 8a and Cr opaque layer 4 and/or CrO AR layer 6. As the endpoint is reached, some surface portions of the substantially transparent material 2 (e.g., quartz) become exposed to the plasma etch environment. The change in the properties of the exposed surfaces and consequent change of gas composition in the plasma etch environment result in the change of the load impedance. Upon monitoring the change in the load impedance, the AMN system 42 adjusts the internal parameters of the plasma-assisted etch system to match the impedance between the RF generator 40 and the process module 44. By monitoring the changes in the etch parameters and subsequent adjustment by the AMN to match the source and load impedances, endpoint information can be collected for control and termination of the plasma-assisted etch process. Because the AMN 42 is already a part of the plasma-assisted etch system, the present invention requires neither any additional equipment or hardware for endpoint detection, nor any complex tool for analyzing the monitored data.

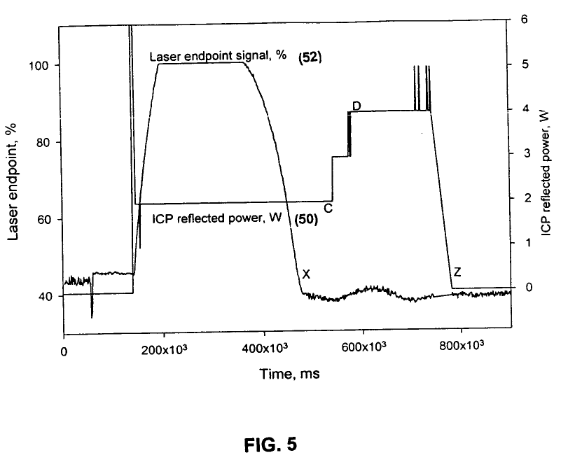

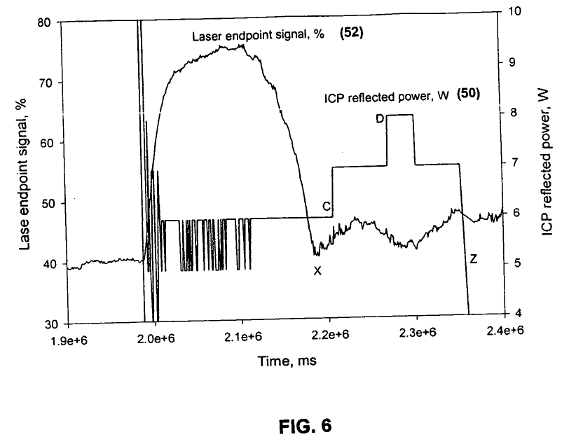

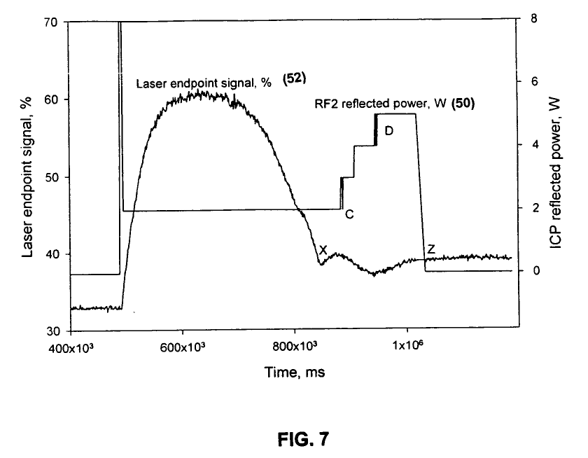

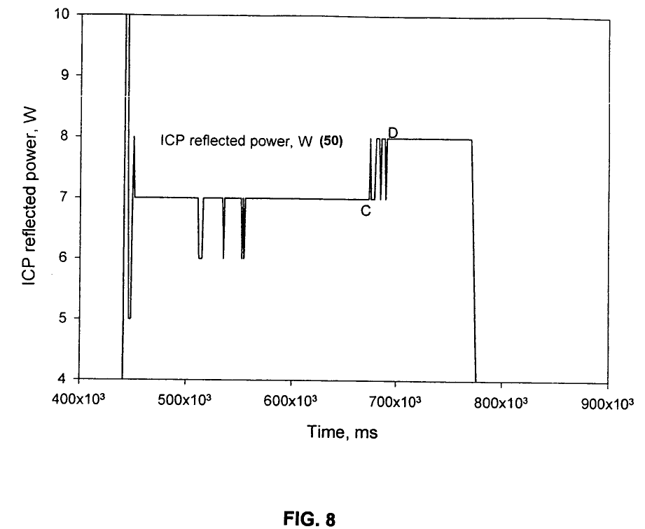

Typically, an etch tool monitor in the AMN 42 displays the monitored signals for several AMN parameters. FIGS. 5-10 display the graphs of the monitored signals for various etch parameters that contain endpoint information. FIG. 5 shows ICP reflected power 50 as a function of time during the plasma-assisted etching of chromium layer in a clear field chromium-resist binary mask. The ICP reflected power 50 undergoes a clear change at the endpoint from C to D. FIG. 6 shows ICP reflected power 50 as a function of time during the plasma-assisted etching of chromium layer in a dark field chromium-resist binary mask. The ICP reflected power 50 undergoes a clear change at the endpoint from C to D. FIG. 7 shows ICP reflected power 50 as a function of time during the plasma-assisted etching of chromium layer in a clear field phaseshift mask. The ICP reflected power 50 undergoes a clear change at the endpoint from C to D. FIG. 8 shows ICP reflected power 50 as a function of time during the plasma-assisted etching of chromium layer in a dark field phaseshift mask. The ICP reflected power 50 undergoes a clear change at the endpoint from C to D.

In FIGS. 5-7, laser endpoint signals 52 generated by the optical interferometric method based on reflection of a laser beam from the etched surface are shown for the purpose of comparison with the endpoint information from the embodiment of the present invention. FIGS. 5-7 show that the endpoint detection at C by the embodiment of the present invention occurs after the endpoint detection at X by the optical interferometric method. Accordingly, the present invention overcomes the deficiency of the prior art optical interferometric method as described earlier, i.e., the problem of issuing a premature endpoint report before the true endpoint over the entire etched surface is reached.

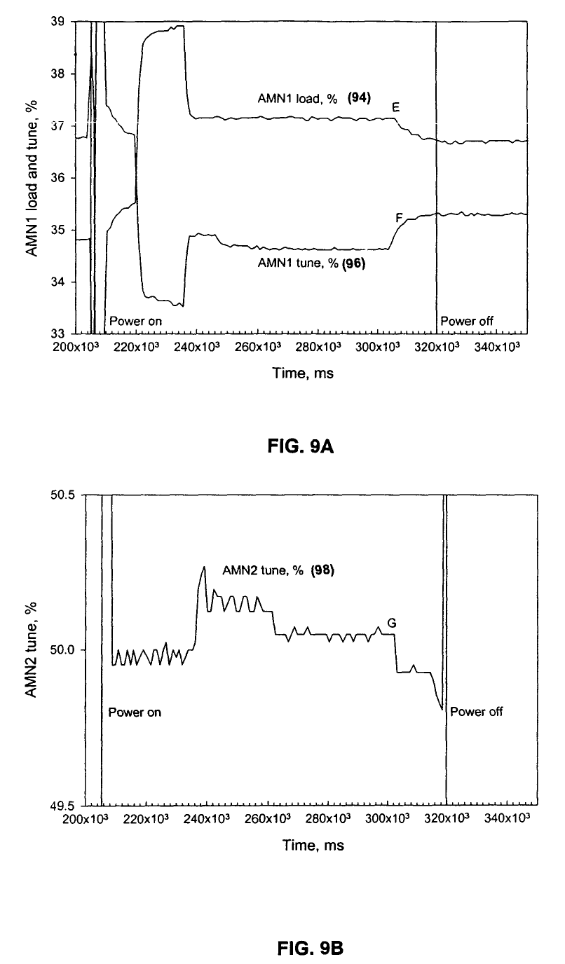

The conventional signal display setting of the etch tool monitor is from 0 to 100%. However, the parameter change at the endpoint may be very small (e.g., about 0.3% from 35.0% to 35.3% as shown in FIG. 9A) and such small change in parameter may not be visible in the signal display in the conventional display setting. Therefore, in another embodiment of the present invention, the signal display setting is modified for zooming-in and re-scaling (e.g., in 33-to-39% scale) of the monitored signals so as to facilitate timely detection of the parameter change at the endpoint. In yet another embodiment of the present invention, an amplifier may be coupled to the etch tool monitor to subtract background noise signals and output amplified signals for the monitored parameters to the display monitor.

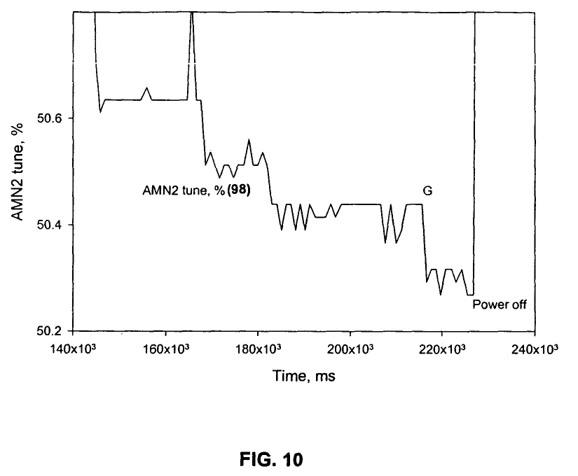

The examples of such enlarged and re-scaled display of the endpoint information are shown in FIGS. 9A, 9B and 10. FIG. 9A shows AMN load 94 and tune 96 for bias RF plasma (“the AMN1 load” and “AMN1 tune,” respectively) as functions of time during plasma-assisted etching of MoSi layer in a clear field phaseshift mask. These AMN load 94 and tune 96 were measured relative to a tool-specific reference value, and their magnitudes are thus given in percentage. In this re-scaled plot, the AMN1 load 94 and tune 96 are shown to undergo a clear change at the endpoint at E and F, respectively. FIG. 9B shows AMN tune 98 for ICP (“the AMN2 tune”) as a function of time during plasma-assisted etching of MoSi layer in a clear field phaseshift mask. The AMN2 tune 98 is shown to undergo a clear change at the endpoint at G. FIG. 10 shows AMN tune 98 for ICP as a function of time during plasma-assisted etching of MoSi layer in a dark field phaseshift mask. The AMN2 tune 98 undergoes a clear change at the endpoint at G.

In addition to the etch parameters shown in FIGS. 7-12, any other etch or AMN parameters, or combination thereof, that are adjusted for impedance matching and display endpoint information can be used for the purpose of endpoint detection according to the present invention. For example, parameters that may be adjusted for impedance matching and exhibit endpoint information include AMN load for ICP (“the AMN2 load”), capacitance of at least one variable capacitor in AMN or any other type of an impedance matching system, inductance of at least one variable inductor in AMN or any other type of an impedance matching system, frequency of a RF source for either ICP or bias RF plasma. Therefore, any one of them may be used for endpoint detection under the present invention. Furthermore, parameter of any kind of AMN system implementation or any type of impedance matching system or device for plasma-assisted etch processes may be used for endpoint detection of the present invention, as long as it provides endpoint information. Therefore, the present invention may be applicable to a wide variety of plasma-assisted etch systems employing different types of impedance-matching systems.

Furthermore, any other etch parameters that display endpoint information may be used for endpoint detection under the present invention. For example, to keep constant pressure in the etch chamber during the plasma-assisted etch process, pump rate of the vacuum pump controlling gas environment within the etch chamber is adjusted by a throttle valve opening. At endpoint, since the total gas flow rate changes, the throttle valve opening changes accordingly. Therefore, the pump rate for evacuating gas from the etch chamber may be used as means for endpoint detection under the present invention.

One important advantage of the present invention over prior art endpoint detection methods is that endpoint detection may be achieved by simply observing a predetermined change in one parameter of plasma-assisted etch process. For example, as shown in FIGS. 5-10, any one of these monitored AMN parameters exhibits a clear observable change at endpoint. Hence, under the present invention, endpoint detection for plasma-assisted etch process may be achieved by monitoring only one parameter of the etch process, without the need to monitor, process and analyze multi-parameter data.

Furthermore, as shown in FIGS. 5-10, these parameter changes at endpoint are or can be known in advance, and therefore one of the parameter changes at endpoint may be designated or predetermined as an endpoint signature for use in endpoint detection, either before or during the plasma-assisted etch process. Unlike the prior art neural-network based endpoint detection method, which requires several “learning” runs of the etch processes to recognize endpoint, the endpoint detection method of the present invention is based on simply recognizing a predetermined change of at least one parameter of the etch process. The endpoint detection of the present invention does not require heavy computational analysis and processes of multi-parameter data during multiple etch runs to recognize endpoint.

Furthermore, as noted earlier, these predetermined changes in the etch parameters (e.g., the AMN parameters as shown in FIGS. 5-10) are already monitored and displayed by the AMN 42 for the purpose of matching the source and load impedances of the plasma-assisted etch system. Therefore, the endpoint detection method of the present invention does not require any additional detecting or display means for the monitored signals (other than possibly means for amplifying the endpoint data signal) exclusively for the purpose of endpoint detection. The endpoint detection of the present invention may easily be implemented with minimum change to the existing etch system hardware.

Because the monitored signals of parameters from photomask etching are found to be sufficiently strong for easy monitoring, endpoint detection may be achieved by monitoring only one parameter. Hence, the endpoint detection method of the present invention is particularly well suited to the plasma-assisted etching of photomasks. Nevertheless, the endpoint detection method of the present invention may be applicable to any products or materials, such as semiconductor wafers, that require plasma-assisted etch process.

In another embodiment of the present invention, the endpoint detection method may be used to further control and terminate the plasma-assisted etch process upon detecting the change in a parameter of the plasma-assisted etch process signaling endpoint. The control and/or termination of the etch process may be performed manually (i.e., by an operator who visually identifies from the signal display monitor the signature change in the parameter at endpoint), or automatically in conjunction with the automatic control system of the plasma-assisted etch system by using, for example, a special algorithm. Generally, modern plasma-assisted etch systems have all of their etch process information stored in a computer in form of digital data. A special algorithm may be used to detect endpoint from monitoring deviations in etch or AMN parameter signal and then to output a control signal to the control system to further control and/or terminate the etch process.

Now that the preferred embodiments of the present invention have been shown and described in detail, various modifications and improvements thereon will become readily apparent to those skilled in the art. For example, the present invention is not limited to CoG photomasks, but also may be applied to other types of binary photomasks. Similarly, the present invention is not limited to EAPSM, but may also apply to other types of phaseshift photomasks, including by way of example, but not limited to, AAPSM. Furthermore, application of the present invention is not limited to the production of photomasks, but may also apply to productions of other types of devices or materials requiring plasma-assisted etch processes, including, but not limited to, semiconductor wafers. The present embodiments are therefore to be considered in all respects as illustrative and not restrictive, the scope of the invention being indicated by the appended claims, and all changes that come within the meaning and range of equivalency of the claims are therefore intended to be embraced therein.

1. A method for detecting endpoint of a plasma-assisted etch process in production of a photomask comprising:
providing a blank photomask comprising a photosensitive resist layer on the top of said blank photomask;
creating soluble and insoluble portions in said photosensitive resist layer;
removing soluble portions of said photosensitive resist layer, thereby exposing an underlying layer of said blank photomask;
commencing said plasma-assisted etch process on said underlying layer of said blank photomask;
defining said endpoint in the form of a predetermined change in at least one of parameters of said plasma-assisted etch process;
monitoring said at least one of said parameters;
detecting said predetermined change in said at least one of said parameters; and
controlling said plasma-assisted etch process based on the detection of said predetermined change in said at least one of said parameters.

2. The method of claim 1, wherein said step of controlling said plasma-assisted etch process comprises the step of terminating said plasma-assisted etch process.

3. The method of claim 1, wherein said step of monitoring said at least one of said parameters further comprises the step of modifying a signal display of said at least one of said parameters to display said predetermined change in said at least one of said parameters.

4. The method of claim 3, wherein said step of modifying said signal display comprises the step of amplifying said signal display.

5. The method of claim 3, wherein said step of modifying said signal display comprises the step of re-scaling said signal display.

6. The method of claim 1, wherein said plasma-assisted etch process uses an automatic matching network.

7. The method of claim 6, wherein said at least one of said parameters is an automatic matching network parameter.

8. The method of claim 1, wherein said controlling step is performed manually.

9. The method of claim 1, wherein said controlling step is performed automatically.

10. The method of claim 9, wherein said automatically controlling step comprises the step of using an algorithm.

11. The method of claim 1, wherein said monitoring step is performed automatically.

12. The method of claim 11, wherein said automatically monitoring step comprises the step of using an algorithm.

13. The method of claim 1, wherein said detecting step is performed automatically.

14. The method of claim 13, wherein said automatically detecting step comprises the step of using an algorithm.

15. The method of claim 1, wherein a plasma for said plasma-assisted etch process comprises bias radio-frequency plasma.

16. The method of claim 1, wherein a plasma for said plasma-assisted etch process comprises inductively coupled plasma.

17. The method of claim 1, wherein a plasma for said plasma-assisted etch process comprises bias radio-frequency plasma and inductively coupled plasma.

18. The method of claim 1, wherein said plasma-assisted etch process comprises a reactive ion etch process.

19. The method of claim 7, wherein said automatic matching network parameter is an automatic matching network load.

20. The method of claim 19, wherein said automatic matching network load is an automatic matching network load for inductively coupled plasma.

21. The method of claim 19, wherein said automatic matching network load is an automatic matching network load for bias radio-frequency plasma.

22. The method of claim 7, wherein said automatic matching network parameter is an automatic matching network tune.

23. The method of claim 22, wherein said automatic matching network tune is an automatic matching network tune for inductively coupled plasma.

24. The method of claim 22, wherein said automatic matching network tune is an automatic matching network tune for bias radio-frequency plasma.

25. The method of claim 22, wherein said automatic matching network tune is a capacitance of at least one variable capacitor in said automatic matching network.

26. The method of claim 1, wherein said at least one of said parameters is a reflected power for inductively coupled plasma.

27. The method of claim 1, wherein said at least one of said parameters is a pump rate of a vacuum pump for said plasma-assisted etch process.

28. The method of claim 1, wherein said photomask is a binary photomask.

29. The method of claim 28, wherein said underlying layer is a chromium layer of said binary photomask.

30. The method of claim 1, wherein said photomask is a phaseshift photomask.

31. The method of claim 30, wherein said underlying layer is a chromium layer of said phaseshift photomask.

32. The method of claim 30, wherein said underlying layer is a MoSi layer of said phaseshift photomask.

33. A method for detecting endpoint of a plasma-assisted etch process in production of a photomask comprising:
providing a blank photomask comprising a photosensitive resist layer on the top of said blank photomask;
creating soluble and insoluble portions in said photosensitive resist layer;
removing soluble portions of said photosensitive resist layer, thereby exposing an underlying layer of said blank photomask;
commencing said plasma-assisted etch process on said underlying layer of said blank photomask;
defining said endpoint in the form of a change in one parameter of said plasma-assisted etch process;
monitoring said one parameter;
detecting said change in said one parameter; and
controlling said plasma-assisted etch process based on the detection of said change in said one parameter.

34. The method of claim 33, wherein said step of controlling said plasma-assisted etch process comprises the step of terminating said plasma-assisted etch process.

35. The method of claim 33, wherein said step of monitoring said one parameter further comprises the step of modifying a signal display of said one parameter to display said change in said one parameter.

36. The method of claim 35, wherein said step of modifying said signal display comprises the step of amplifying said signal display.

37. The method of claim 35, wherein said step of modifying said signal display comprises the step of re-scaling said signal display.

38. The method of claim 33, wherein said plasma-assisted etch process uses an automatic matching network.

39. The method of claim 38, wherein said one parameter is an automatic matching network parameter.

40. The method of claim 33, wherein said controlling step is performed manually.

41. The method of claim 33, wherein said controlling step is performed automatically.

42. The method of claim 41, wherein said automatically controlling step comprises the step of using an algorithm.

43. The method of claim 33, wherein said monitoring step is performed automatically.

44. The method of claim 43, wherein said automatically monitoring step comprises the step of using an algorithm.

45. The method of claim 33, wherein said detecting step is performed automatically.

46. The method of claim 45, wherein said automatically detecting step comprises the step of using an algorithm.

47. The method of claim 33, wherein a plasma for said plasma-assisted etch process comprises bias radio-frequency plasma.

48. The method of claim 33, wherein a plasma for said plasma-assisted etch process comprises inductively coupled plasma.

49. The method of claim 33, wherein a plasma for said plasma-assisted etch process comprises bias radio-frequency plasma and inductively coupled plasma.

50. The method of claim 33, wherein said plasma-assisted etch process comprises a reactive ion etch process.

51. The method of claim 39, wherein said automatic matching network parameter is an automatic matching network load.

52. The method of claim 51, wherein said automatic matching network load is an automatic matching network load for inductively coupled plasma.

53. The method of claim 51, wherein said automatic matching network load is an automatic matching network load for bias radio-frequency plasma.

54. The method of claim 39, wherein said automatic matching network parameter is an automatic matching network tune.

55. The method of claim 54, wherein said automatic matching network tune is an automatic matching network tune for inductively coupled plasma.

56. The method of claim 54, wherein said automatic matching network tune is an automatic matching network tune for bias radio-frequency plasma.

57. The method of claim 54, wherein said automatic matching network tune is a capacitance of at least one variable capacitor in said automatic matching network.

58. The method of claim 33, wherein said one parameter is a reflected power for inductively coupled plasma.

59. The method of claim 33, wherein said one parameter is a pump rate of a vacuum pump for said plasma-assisted etch process.

60. The method of claim 33, wherein said photomask is a binary photomask.

61. The method of claim 60, wherein said underlying layer is a chromium layer of said binary photomask.

62. The method of claim 33, wherein said photomask is a phaseshift photomask.

63. The method of claim 62, wherein said underlying layer is a chromium layer of said phaseshift photomask.

64. The method of claim 62, wherein said underlying layer is a MoSi layer of said phaseshift photomask.

65. A method for detecting endpoint of a plasma-assisted etch process in production of a photomask, wherein said plasma-assisted etch process uses an automatic matching network, said method comprising:
providing a blank photomask comprising a photosensitive resist layer on the top of said blank photomask;
creating soluble and insoluble portions in said photosensitive resist layer;
removing soluble portions of said photosensitive resist layer, thereby exposing an underlying layer of said blank photomask;
commencing said plasma-assisted etch process on said underlying layer of said blank photomask;
defining said endpoint in the form of a predetermined change in at least one of automatic matching network parameters of said plasma-assisted etch process;
monitoring said at least one of said automatic matching network parameters;
detecting said predetermined change in said at least one of said automatic matching network parameters; and
controlling said plasma-assisted etch process based on the detection of said predetermined change in said at least one of said automatic matching network parameters.

66. The method of claim 65, wherein said step of controlling said plasma-assisted etch process comprises the step of terminating said plasma-assisted etch process.

67. The method of claim 65, wherein said step of monitoring said at least one of said parameters further comprises the step of modifying a signal display of said at least one of said parameters to display said predetermined change in said at least one of said parameters.

68. The method of claim 67, wherein said step of modifying said signal display comprises the step of amplifying said signal display.

69. The method of claim 67, wherein said step of modifying said signal display comprises the step of re-scaling said signal display.

70. The method of claim 65, wherein said controlling step is performed manually.

71. The method of claim 65, wherein said controlling step is performed automatically.

72. The method of claim 71, wherein said automatically controlling step comprises the step of using an algorithm.

73. The method of claim 65, wherein said monitoring step is performed automatically.

74. The method of claim 73, wherein said automatically monitoring step comprises the step of using an algorithm.

75. The method of claim 65, wherein said detecting step is performed automatically.

76. The method of claim 75, wherein said automatically detecting step comprises the step of using an algorithm.

77. The method of claim 65, wherein a plasma for said plasma-assisted etch process comprises bias radio-frequency plasma.

78. The method of claim 65, wherein a plasma for said plasma-assisted etch process comprises inductively coupled plasma.

79. The method of claim 65, wherein a plasma for said plasma-assisted etch process comprises bias radio-frequency plasma and inductively coupled plasma.

80. The method of claim 65, wherein said plasma-assisted etch process comprises a reactive ion etch process.

81. The method of claim 65, wherein said at least one of said automatic matching network parameters is an automatic matching network load.

82. The method of claim 81, wherein said automatic matching network load is an automatic matching network load for inductively coupled plasma.

83. The method of claim 81, wherein said automatic matching network load is an automatic matching network load for bias radio-frequency plasma.

84. The method of claim 65, wherein said at least one of said automatic matching network parameters is an automatic matching network tune.

85. The method of claim 84, wherein said automatic matching network tune is an automatic matching network tune for inductively coupled plasma.

86. The method of claim 84, wherein said automatic matching network tune is an automatic matching network tune for bias radio-frequency plasma.

87. The method of claim 84, wherein said automatic matching network tune is a capacitance of at least one variable capacitor in said automatic matching network.

88. The method of claim 65, wherein said at least one of said automatic matching network parameters is a reflected power for inductively coupled plasma.

89. The method of claim 65, wherein said photomask is a binary photomask.

90. The method of claim 89, wherein said underlying layer is a chromium layer of said binary photomask.

91. The method of claim 65, wherein said photomask is a phaseshift photomask.

92. The method of claim 91, wherein said underlying layer is a chromium layer of said phaseshift photomask.

93. The method of claim 91, wherein said underlying layer is a MoSi layer of said phaseshift photomask.
